(19) United States
(12) Patent Application Publication
(10) Pub. No.: US 2025/0174470 A1
(43) Pub. Date: May 29, 2025

(54) METHOD FOR METALLIZATION THROUGH-GLASS VIAS AND A GLASS ARTICLE MANUFACUTURED THEREOF

(71) Applicant: CORNING INCORPORATED, CORNING, NY (US)

(72) Inventors: Mandakini Kanungo, Ithaca, NY (US); Prantik Mazumder, Ithaca, NY (US); Rajesh Vaddi, Horseheads, NY (US)

(21) Appl. No.: 18/919,498

(22) Filed: Oct. 18, 2024

Related U.S. Application Data
(60) Provisional application No. 63/603,194, filed on Nov. 28, 2023.

(51) Int. Cl. H01L 21/48; H01L 23/15; H01L 23/498

(52) U.S. Cl. CPC H01L 21/486; H01L 23/15; H01L 23/49827

(57) ABSTRACT

A method for metallizing through-glass vias in a glass substrate includes a) cleaning a glass substrate, wherein the glass substrate having an A side surface and a B side surface opposite the A side surface and separated from the A side surface by a thickness t, and a plurality of vias extending through the glass substrate from A side surface to the B side surface; b) depositing of an adhesion layer onto both the A side surface and B side surface of the glass substrate; c) laminating of a first dry film resist (DFR) onto the adhesion layer on the A side surface and a second DFR onto the adhesion layer on the B side surface of the glass substrate; d) making a pattern on the second DFR on the B side surface, and removing the second DFR elsewhere on the B side surface; e) etching the adhesion layer on the B side surface everywhere except underneath the pattern of the second DFR on B side surface; f) removing the pattern of the second DFR from B side surface so as to expose the vias; g) applying a current to the A side surface so as to reduce copper ions into copper and maintaining the B side surface vias electrically isolated.

### CROSS REFERENCE TO RELATED APPLICATION

This application claims the benefit of priority under 35 U.S.C. § 119 of U.S. Provisional Application Ser. No. 63/603,194 filed on Nov. 28, 2023, the content of which is relied upon and incorporated herein by reference in its entirety.

### BACKGROUND

### Field

The present specification generally relates to the manufacture of through-glass vias and, more specifically, to copper metallization of through-glass vias.

### Technical Background

Through-substrate vias provide electrical connections between layers in a physical electronic circuit or chip. For example, in a three-dimensional stacked integrated circuit, the through-substrate vias enable integration of electronic components both vertically and horizontally. Conventionally, through-substrate vias are used in organic and silicon substrates. However, because glass is less expensive than silicon, glass substrates are becoming more prevalent in electronic devices. Glass substrates may also provide improved electromagnetic loss properties, improved dielectric properties, tailorable coefficients of thermal expansion, and the ability to come in scalable form factors, including roll-to-roll forms. With all the advantages mentioned above, and the need for smaller via diameters which leads to high aspect ratio, the realization of Cu metallization in the vias is critical for such applications.

Conventional processes for metallizing vias include dry and wet methods. Dry processes like physical vapor deposition (PVD) and chemical vapor deposition (CVD) are carried out in a vacuum environment, leading to limited throughput and increased manufacturing costs. Moreover, these dry processes face challenges in producing continuous metal layers within glass vias with aspect ratios greater than 5, particularly for small diameters (e.g., less than 50 μm). Wet processes, such as electroless plating, offer cost-effectiveness but often result in voids or seams in through-glass vias with high aspect ratios, requiring complex chemistries and process optimization. Achieving both hermeticity and thermomechanical reliability in these vias remains a challenge.

Therefore, there is a need for alternative methods to metallize through-glass vias, especially those with small diameters.

### SUMMARY

According to various aspects disclosed herein, a method for metallizing through-glass vias in a glass substrate includes a) cleaning a glass substrate, wherein the glass substrate having an A side surface and a B side surface opposite the A side surface and separated from the A side surface by a thickness t, and a plurality of vias extending through the glass substrate from A side surface to the B side surface; b) depositing of an adhesion layer onto both the A side surface and B side surface of the glass substrate; c) laminating of a first dry film resist (DFR) onto the adhesion layer on the A side surface and a second DFR onto the adhesion layer on the B side surface of the glass substrate; d) making a pattern on the second DFR on the B side surface, and removing the second DFR elsewhere on the B side surface; e) etching the adhesion layer on the B side surface everywhere except underneath the pattern of the second DER on B side surface; f) removing the pattern of the second DFR from B side surface so as to expose the vias; g) applying a current to the A side surface so as to reduce copper ions into copper and maintaining the B side surface vias electrically isolated.

Another aspect includes the method of the previous aspect, wherein the pattern of the second DFR on the B side surface comprises a plurality of patches covering the vias of the glass substrate, wherein the plurality of patches are disconnected from each other.

Another aspect includes the method of the previous aspect, wherein the area of the patches is larger than the area of the vias so as to cover the vias.

Another aspect includes the method of the previous aspect, wherein the patches having an area 1.2 to 2 times of the area of the vias.

Another aspect includes the method of the previous aspect, wherein the adhesion layer is selected from at least one of titanium/copper (Ti/Cu), titanium tungsten/copper (TiW/Cu), titanium/nickel (Ti/Ni), titanium nitride (TiN), tantalum nitride (TaN), ruthenium (Ru), chromium/copper (Cr/Cu), and palladium (Pd).

Another aspect includes the method of the previous aspect, wherein the first DFR is applied continuously over the A side surface of the glass substrate.

Another aspect includes the method of the previous aspect, wherein the thickness t of the glass substrate is greater than or equal to 50 μm and less than or equal to 1200 μm.

Another aspect includes the method of the previous aspect, wherein the vias have an average diameter of greater than or equal to 5 μm and less than or equal to 150 μm.

According to another aspect, a glass article includes a glass substrate having an A side surface and a B side surface opposite the A side surface and separated from the A side surface by a thickness t; wherein t is greater than or equal to 50 μm and less than or equal to 1200 μm; a plurality of vias extending through the glass substrate from A side surface to the B side surface, wherein: the vias have an average diameter of greater than or equal to 5 μm and less than or equal to 150 μm; an aspect ratio of the thickness of the glass substrate to the average diameter of the plurality of vias is greater than 12:1 and less than or equal to 150:1; the plurality of vias is filled with copper; wherein an adhesion layer is present at the via entrances connecting copper and a sidewall of glass substrate.

Another aspect includes the glass article of the previous aspect, wherein the copper also covers a portion of the outer perimeter of the vias on at least one side of the surfaces of the glass substrate, wherein the area of the portion is 1.2 to 2 times the area of the vias.

Another aspect includes the glass article of the previous aspect, wherein the adhesion layer is selected from at least one of titanium/copper (Ti/Cu), titanium tungsten/copper (TiW/Cu), titanium/nickel (Ti/Ni), titanium nitride (TiN), tantalum nitride (TaN), ruthenium (Ru), chromium/copper (Cr/Cu), and palladium (Pd).

Another aspect includes the glass article of the previous aspect, wherein the adhesion layer has a thickness ranging from 60 nm to 1500 nm.

Additional features and advantages will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a cross-section of a glass substrate including a plurality of vias in accordance with one or more embodiments shown and described herein;

FIG. 2 Method for metallizing the plurality of vias in accordance with one or more embodiments shown and described herein;

FIG. 3 schematically depicts a cross-section of a glass substrate having an adhesion layer deposited onto both the A side surface and B side surface of the glass substrate in accordance with one or more embodiments shown and described herein;

FIG. 4 schematically depicts a cross-section of a glass substrate having a first dry film resist (DFR) onto the adhesion layer on the A side surface and a second DFR onto the onto the adhesion layer on the B side surface of the glass substrate in accordance with one or more embodiments shown and described herein;

FIG. 5 schematically depicts a cross-section of a glass substrate having a pattern on the second DFR on the B side surface in accordance with one or more embodiments shown and described herein;

FIG. 6 schematically depicts a cross-section of a glass substrate having an adhesion layer underneath the pattern of the second DFR on B side surface in accordance with one or more embodiments shown and described herein;

FIG. 7 schematically depicts a cross-section of a glass substrate with exposed vias on B side surface in accordance with one or more embodiments shown and described herein;

FIG. 8 schematically depicts applying a current to the A side surface so as to reduce copper ions into copper and maintaining the B side surface vias electrically isolated in accordance with one or more embodiments shown and described herein;

FIG. 9 schematically depicts a cross-section of a glass substrate with a plurality of vias filled with copper and an adhesion layer is present at the via entrances connecting copper and the glass substrate;

FIG. 10 schematically depicts a cross-section of a glass substrate with a plurality of vias filled with copper and the copper also covers a portion of the outer perimeter of the vias on at least one side of the surfaces of the glass substrate;

FIG. 11 is XRM image showing the complete and void-free filling of the 20 um via diameters in 350 um thick glass substrate with the copper in accordance with one or more embodiments shown and described herein.

### DETAILED DESCRIPTION

Reference will now be made in detail to various embodiments, examples of which are illustrated in the accompanying drawings. Whenever possible, the same reference numerals will be used throughout the drawings to refer to the same or like parts.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise. Also, the word “or” when used without a preceding “either” (or other similar language indicating that “or” is unequivocally meant to be exclusive—e.g., only one of x or y, etc.) shall be interpreted to be inclusive (e.g., “x or y” means one or both x or y).

The term “and/or” shall also be interpreted to be inclusive (e.g., “x and/or y” means one or both x or y). In situations where “and/or” or “or” are used as a conjunction for a group of three or more items, the group should be interpreted to include one item alone, all the items together, or any combination or number of the items. Moreover, terms used in the specification and claims such as have, having, include, and including should be construed to be synonymous with the terms comprise and comprising.

As used herein, the term “aspect ratio” refers to the ratio of the thickness t of the glass substrate to the average diameter of the plurality of vias.

Unless otherwise indicated, all numbers or expressions, such as those expressing dimensions, physical characteristics, and the like, used in the specification (other than the claims) are understood to be modified in all instances by the term “approximately.” At the very least, and not as an attempt to limit the application of the doctrine of equivalents to the claims, each numerical parameter recited in the specification or claims which is modified by the term “approximately” should be construed in light of the number of recited significant digits and by applying ordinary rounding techniques.

All disclosed ranges are to be understood to encompass and provide support for claims that recite any and all subranges or any and all individual values subsumed by each range. For example, a stated range of 1 to 10 should be considered to include and provide support for claims that recite any and all subranges or individual values that are between and/or inclusive of the minimum value of 1 and the maximum value of 10; that is, all subranges beginning with a minimum value of 1 or more and ending with a maximum value of 10 or less (e.g., 5.5 to 10, 2.34 to 3.56, and so forth) or any values from 1 to 10 (e.g., 3, 5.8, 9.9994, and so forth).

All disclosed numerical values are to be understood as being variable from 0-100% in either direction and thus provide support for claims that recite such values or any and all ranges or subranges that can be formed by such values. For example, a stated numerical value of 8 should be understood to vary from 0 to 16 (100% in either direction) and provide support for claims that recite the range itself (e.g., 0 to 16), any subrange within the range (e.g., 2 to 12.5) or any individual value within that range (e.g., 15.2).

The drawings shall be interpreted as illustrating one or more embodiments that are drawn to scale and/or one or more embodiments that are not drawn to scale. This means the drawings can be interpreted, for example, as showing: (a) everything drawn to scale, (b) nothing drawn to scale, or (c) one or more features drawn to scale and one or more features not drawn to scale. Accordingly, the drawings can serve to provide support to recite the sizes, proportions, and/or other dimensions of any of the illustrated features either alone or relative to each other. Furthermore, all such sizes, proportions, and/or other dimensions are to be understood as being variable from 0-100% in either direction and thus provide support for claims that recite such values or any and all ranges or subranges that can be formed by such values.

The terms recited in the claims should be given their ordinary and customary meaning as determined by reference to relevant entries in widely used general dictionaries and/or relevant technical dictionaries, commonly understood meanings by those in the art, etc., with the understanding that the broadest meaning imparted by any one or combination of these sources should be given to the claim terms (e.g., two or more relevant dictionary entries should be combined to provide the broadest meaning of the combination of entries, etc.) subject only to the following exceptions: (a) if a term is used in a manner that is more expansive than its ordinary and customary meaning, the term should be given its ordinary and customary meaning plus the additional expansive meaning, or (b) if a term has been explicitly defined to have a different meaning by reciting the term followed by the phrase “as used in this document shall mean” or similar language (e.g., “this term means,” “this term is defined as,” “for the purposes of this disclosure this term shall mean,” etc.). References to specific examples, use of “i.e.,” use of the word “invention,” etc., are not meant to invoke exception (b) or otherwise restrict the scope of the recited claim terms. Other than situations where exception (b) applies, nothing contained in this document should be considered a disclaimer or disavowal of claim scope.

In the three-dimensional integrated circuit (3D-IC) industry, stacking devices is a technique being used to increase device performance in a limited space. The performance of the integrated circuit may be further enhanced through the use of smaller vias, which leads to higher aspect ratios (e.g., aspect ratios the thickness of the glass substrate to the average diameter of the via of greater than or equal to 4:1). However, the higher the aspect ratio, the more difficult it is to metallize the sidewalls of the vias, particularly when the vias have small (e.g., less than or equal to 50 μm) diameters. One of the main challenges of metallized through glass vias is achieving both hermeticity (liquid and/or Helium) and thermomechanical reliability. Due to the difference in CTE (coefficient of thermal expansion) between glass (0-8 ppm/° C.) and Cu (16 ppm/° C.), significant stress is generated during any high-temperature processing. This often leads to cracking of the glass substrate or delamination of the Cu from the TGV wall, both of which are detrimental to the final performance of the device.

The methods of the present disclosure enable through-glass vias to be filled with an electrically conductive material, such as copper or another metal, despite the challenges associated with the glass substrate having an aspect ratio of greater than 12:1.

In the embodiment shown in FIG. 1, the glass article is in the form of a glass substrate 100 that includes a plurality of vias 106, or precision holes, defined by one or more sidewalls 108. For example, in the embodiments described herein, the vias 106 are circular in cross section and, as such, the vias 106 have sidewall 108. However, it should be understood that vias with other cross-sectional geometries are contemplated include, for example vias which have more than one sidewall. The glass substrate 100 may be used, for example, as an interposer to provide vertical electrical connections within a three-dimensional integrated circuit. The glass substrate 100 comprises an A side face 102 and a B side face 104 opposite the A side surface 102. The A side surface 102 of the glass substrate 100 is separated from the B side surface 104 of the glass substrate 100 by a thickness t of the glass substrate.

The composition of the glass substrate 100 is not particularly limited and may be selected based on the desired end use of the glass substrate 100. In some embodiments, the glass substrate 100 may be a flexible glass substrate. The glass substrate 100 may be formed from glasses suitable for electronics applications including, for example, WILLOW® Glass®, Eagle XG™ glass, manufactured by Corning, Inc. However, it should be understood that other glasses are contemplated and possible. For example, other types of ion-exchangeable glasses or fused silica may be used to form the glass substrate 100. Additionally, the glass substrate 100 may be in the shape of a wafer having a 10 cm, 15 cm, 20 cm, 30 cm, or 50 cm diameter, for example. However, it should be understood that glass substrate 100 of other dimensions are contemplated and possible. The thickness of the glass substrate 100 may also vary depending on its end use, although in various embodiments, the thickness t of the glass substrate is greater than or equal to 50 μm and less than or equal to 1200 μm. For example, the glass substrate 100 may have a thickness of from greater than or equal to 200 μm and less than or equal to 400 μm. In various embodiments, the glass substrate 100 has a thickness of more than or equal to about 300 μm. However, it should be understood that glass substrates of any suitable thickness may be utilized. In some embodiments, the thickness of the glass substrate may be measured through interferometric methods at locations within the area of the substrate. Additionally, or alternatively, mechanical means (e.g., calipers) may be used to measure the thickness of the glass substrate. Unless otherwise specified, thickness of the glass substrate is measured by interferometric methods.

The plurality of vias 106 can be formed in the glass substrate 100 by any suitable method. For example, in some embodiments, the plurality of vias 106 may be drilled in the glass substrate 100 using a pulsed laser. The laser may be any laser having suitable optical properties for drilling through the glass substrate 100 as well as a sacrificial cover layer positioned on a surface of the glass substrate 100. Suitable lasers include, without limitation, ultra-violet (UV) lasers, such as frequency tripled neodymium doped yttrium orthovanadate (Nd:YVO₄) lasers, which emit a beam of coherent light having a wavelength of about 355 nm. The beam of the laser may be directed onto a predetermined location on the surface of the glass substrate and pulsed to form each of the plurality of vias 106 in the glass substrate 100. Alternatively, the plurality of vias may be mechanically machined.

In some embodiments, a diameter of an opening of a via 106 in A side surface 104 of the glass substrate 100 and a diameter of an opening of the via 106 in B side surface 104 of the glass substrate 100 may be the same such that the via 106 is cylindrical. Alternatively, a diameter of an opening of a via 106 in A side surface 102 of the glass substrate 100 and a diameter of an opening of the via 106 in B side surface 104 of the glass substrate 100 may differ by 2 μm or less, such that the via is substantially cylindrical. In other embodiments, a diameter of the vias 106 may decrease from one face of the glass substrate 100 to the other face of the glass substrate 100 such that the vias have a cone shape. In various embodiments, each of the plurality of vias 106 has an average diameter of greater than or equal to 8 μm and less than or equal to 30 μm, or greater than or equal to 8 μm and less than or equal to 15 μm. For example, each of the plurality of vias may have an average diameter of about 20 μm, about 15 μm, about 12 μm, or about 10 μm. As used herein, the term “average diameter” refers to the diameter of the via normal to the axis of the via through the thickness of the glass, averaged along the axis of the via. In some embodiments, the average diameter is measured using an SEM cross-section or visual metrology from the top/bottom side (e.g., averaging the top, waist (or some location within the via within the thickness of the glass), and the bottom). Unless otherwise specified, the average diameter is measured using an SEM cross-section.

According to various embodiments, the aspect ratio is greater than or equal to 12:1, or greater than or equal to 20:1. For example, the aspect ratio may be greater than 12:1 and less than or equal to 150:1, or greater than or equal to 20:1 and less than or equal to 80:1. or greater than or equal to 30:1 and less than or equal to 50:1.

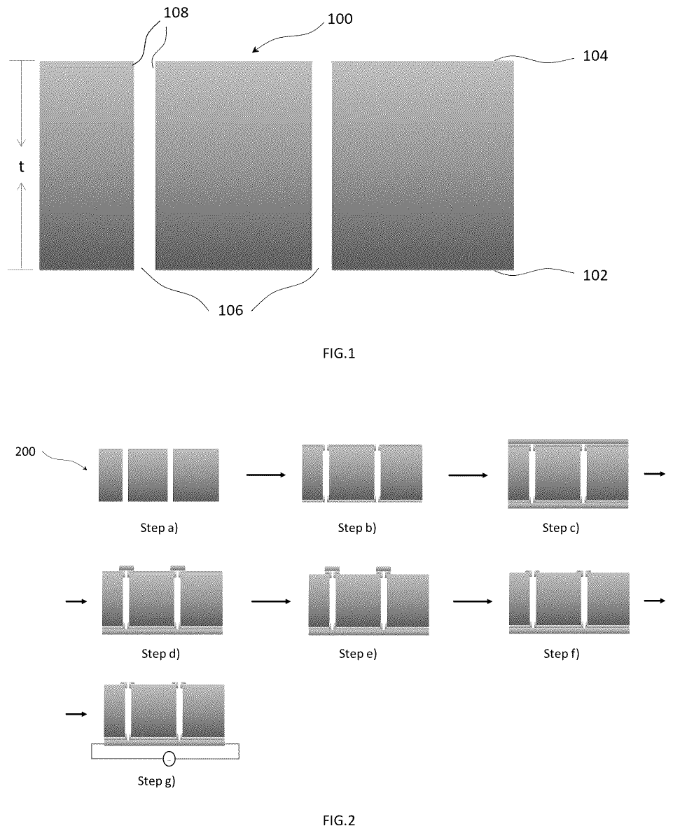

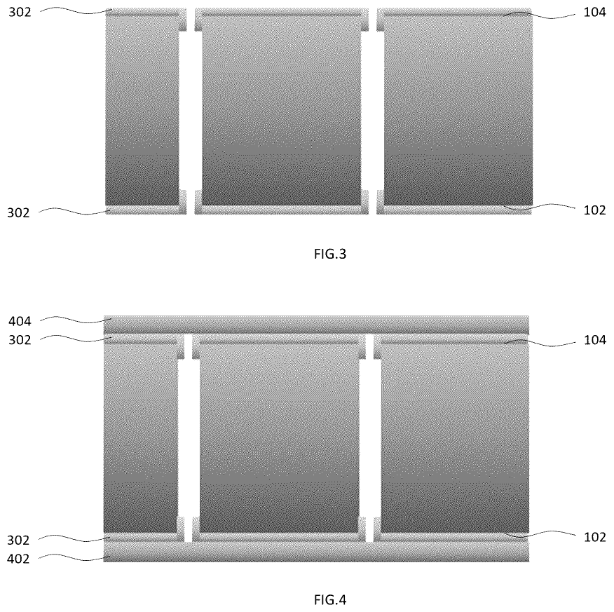

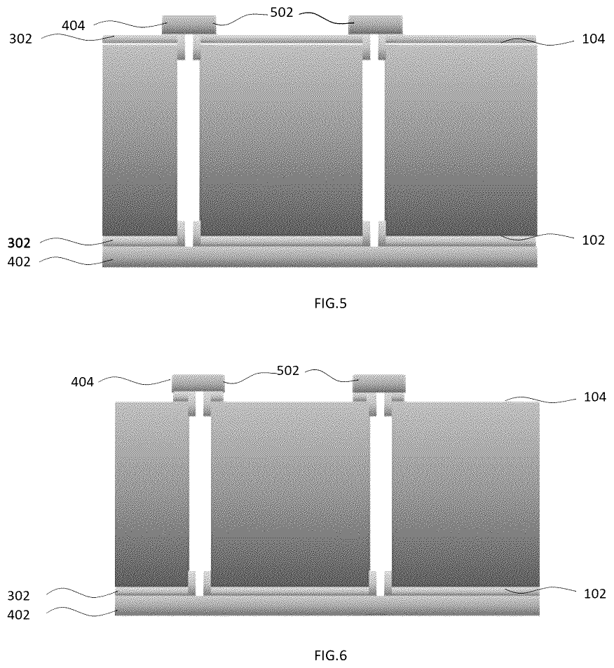

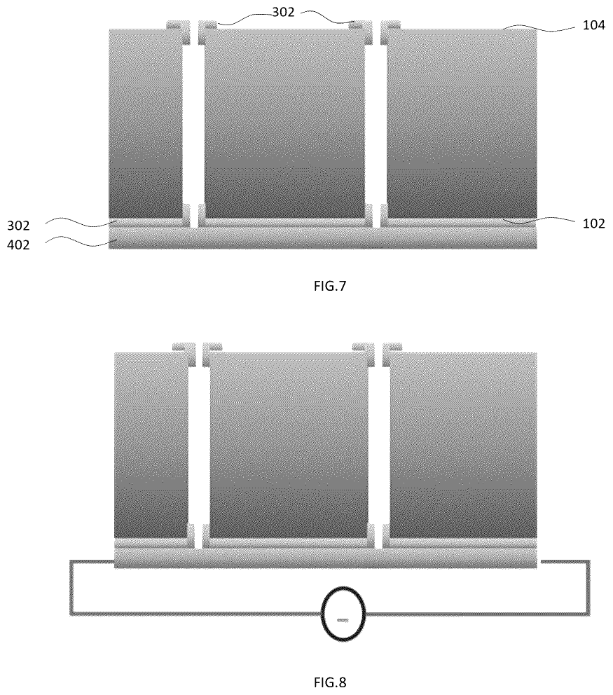

FIG. 2 depicts one embodiment of a method 200 for filling, or metallizing, the vias with the electrically conductive material. In particular, as shown in FIG. 2, the method generally includes a) cleaning a glass substrate, wherein the glass substrate having an A side surface and a B side surface opposite the A side surface and separated from the A side surface by a thickness t, and a plurality of vias extending through the glass substrate from A side surface to the B side surface; b) depositing of an adhesion layer onto both the A side surface and B side surface of the glass substrate (FIG. 3); c) laminating of a first dry film resist (DFR) onto the adhesion layer on the A side surface and a second DFR onto the adhesion layer on the B side surface of the glass substrate (FIG. 4); d) making a pattern on the second DFR on the B side surface, and removing the second DFR elsewhere on the B side surface (FIG. 5); e) etching the adhesion layer on the B side surface everywhere except underneath the pattern of the second DFR on B side surface (FIG. 6); f) removing the pattern of the second DFR from B side surface so as to expose the vias (FIG. 7); g) applying a current to the A side surface so as to reduce copper ions into copper and maintaining the B side surface vias electrically isolated (FIG. 3).

In some embodiments, cleaning may be performed according to any conventional cleaning process known and used in the art to remove organic residues and enrich hydroxyl groups on the surface of the glass substrate. For example, the glass substrate may be cleaned by a process such as O₂ plasma, UV-ozone, or RCA cleaning to remove organics and other impurities (metals, for example) that would interfere with the silane reacting with the surface silanol groups. Washes based on other chemistries may also be used, for example, HF or H₂SO₄ wash chemistries. In some embodiments, the glass substrate may be cleaned with a detergent in an ultrasonic bath and rinsed with deionized water. In various embodiments, the glass substrate has a water contact angle of less than or equal to 7 degrees, less than or equal to 6 degrees, less than or equal to 5 degrees after cleaning, less than or equal to 4 degrees, or less than or equal to 2 degrees as measured using an goniometer, such as DSA100 available from Kruss GmbH (Germany).

Referring to FIG. 3, in some embodiments, at step b), the adhesion layer 302 is deposited on A side surface 102 and B side surface 104. The adhesion layer 302 is selected from at least one of titanium/copper (Ti/Cu), titanium tungsten/copper (TiW/Cu), titanium/nickel (Ti/Ni), titanium nitride (TiN), tantalum nitride (TaN), ruthenium (Ru), chromium/copper (Cr/Cu), and palladium (Pd). In some embodiment, the adhesion layer 302 is sputtered titanium/copper. In some embodiments, the adhesion layer is applied on the surface of the glass substrate through solution processed metal oxide or polyimide. In some embodiments, the adhesion layer is applied on the surface of the glass substrate 100 and one or more of the sidewall(s) 108 of the plurality of vias 106, the A side surface 102 of the glass substrate 100, and the second B side surface 104 of the glass substrate 100. In some embodiments, the adhesion layer 302 is partial applied in the vias 106. In some embodiments, the thickness of the adhesion layer 302 ranges from 60 nm to 1500 nm, with a range of 10 nm to 500 nm for the Ti and a range of 50 nm to 1000 nm for the Cu. It particularly prefers to 100 nm to 500 nm, with a range of 20 nm to 100 nm for the Ti and a range of 80 nm to 400 nm for the Cu. The presence of robust adhesion layers near the via entries fulfills two key functions: (1) they provide helium and liquid hermeticity, and (2) they ensure minimal metal protrusion during thermal cycling.

At step c), as shown in FIG. 4, the A side surface 102 and B side surface 104 are laminated with a first DFR 402 and a second DFR 404 onto the adhesion layer respectively. The first DFR is applied continuously over the A side surface of the glass substrate. DFR is chosen so as to prevent any lateral growth of copper. DFR is a negative tone dry film polymer that can be laminated on the TGV glass. Suitable DFR may include, by way of example and not limitation, commercially available product such as, Ordyl SY 300, DuPont Riston (MX515), Dynachem Ultra 2000, Asahi Chemical Sunfort, and AZ nLOF 2020. In some embodiments, the thickness of the a first DFR 402 and a second DFR 404 is in a range from 5 um to 50 um.

In some embodiments, step d) as depicted in FIG. 5, involves making the second DFR 404 on the B side surface 104, and removing the second DFR 404 elsewhere on the B side surface 104. After step c), the second DFR 404 is exposed to UV light (265 nm) through a mask reticle, utilizing either a contact aligner or stepper tool. The areas exposed to the UV light undergo crosslinking and remain on the substrate forming a pattern, while the unexposed areas are subsequently removed from the resist. The pattern of the second DFR 404 on the B side surface 104 comprises a plurality of patches 502 covering the vias 106 of the glass substrate 100, and the plurality of patches 502 are disconnected from each other. In some embodiments, the patches are larger than the area of the vias so as to cover the vias. In some embodiments, the patches having an area 1.2 to 2 times of the area of the vias.

In some embodiments, as illustrated in FIG. 6, step e) entails the etching of the adhesion layer 302 on the B side surface 104, sparing only the areas beneath the pattern of the second DFR 404 on the B side surface 104. In some embodiments, the removal of the adhesion layer is achieved through a two-step process involving copper (Cu) etching followed by titanium (Ti) etching, a method known as wet etching. Then, as depicted in FIG. 7, step f) involves the removal of the pattern of the second DFR 404 from the B side surface 104, thereby exposing the vias 106.

As depicted in FIG. 8, step g) in some embodiments involves applying a current to the A side surface 102 to reduce copper ions into copper, while keeping the vias 106 on the B side surface 104 electrically isolated. The metallization process is conducted in a constant current mode, using a copper anode current density ranging from 1 mA/cm² to 20 mA/cm² for 1 to 10 hours, followed by a current density of 1 mA/cm² to 20 mA/cm² for 3 to 15 hours. It is important to note that the current is applied solely to the A side surface 104 of the glass substrate 100 laminated with the first DFR 402, directing the copper growth to be one-dimensional within the vias 106. This method ensures that the Cu growth in the vias is controlled by effectively pinching off one side of the via entrance with Cu. In some embodiments in which the electrolyte includes copper ions, the copper ions are reduced into copper within the plurality of vias such that each of the plurality of vias is filled with copper. In some particular embodiments, the electrolyte is an electrolyte bath consisting of CuSO₄, H₂SO₄, Cupracid TP Leveler and Cupracid Brightene. In such embodiments, the CuSO₄ provides a source of copper ions, while the H₂SO₄, makes the bath conductive and acts as a charge carrier. The current density, in various embodiments, is constant. However, the current density may be varied during the electroplating process.

In some embodiments, the electroplated glass substrate may be thermally annealed (not shown in FIG. 2) after the electrically conductive material is deposited thereon to relieve the stress in the glass substrate and reduce the impact of any downstream thermal processing steps. For example, the glass substrate may be heated to a temperature of greater than or equal to 400° C. for a time period sufficient to release the stresses.

The advantages of this method include: 1) The absence of dimples or open cavities near the via entries, enabling the attainment of helium-hermetic, liquid-hermetic, and thermo-mechanically reliable metallized TGVs even at high temperatures (above 400° C.). 2) The process eliminates the need for complex additive chemistries such as suppressors, levelers, and accelerators. 3) It allows for seam and void-free full metallization of small diameter TGVs (less than 15 um diameter) in thick substrates. 4) The method restricts the deposition of copper (Cu) solely to the vias, resulting in minimal or no Cu deposition at the lateral areas of the substrate.

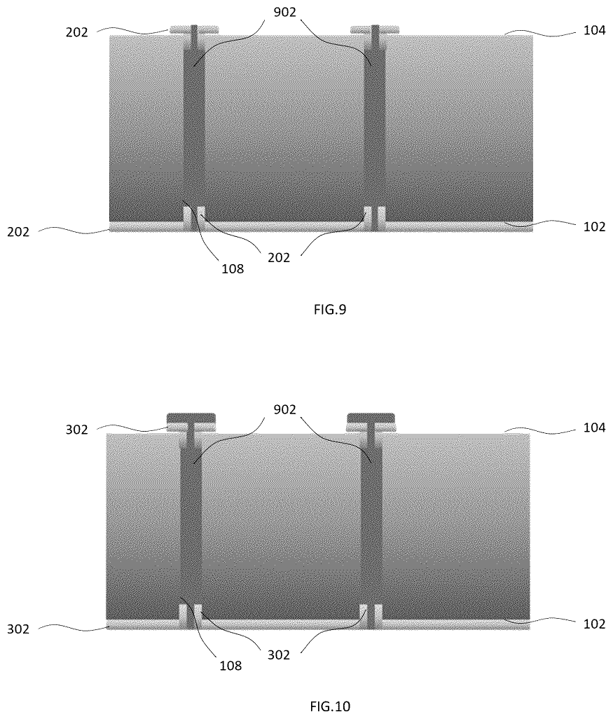

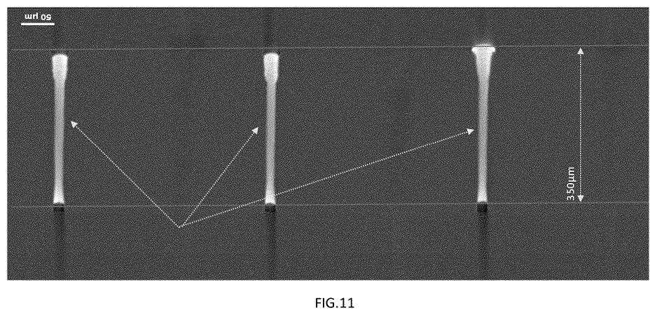

In the embodiments described herein, the plurality of vias 106 is filled with an electrically conductive material 902 (shown in FIG. 9 and FIG. 10). The electrically conductive material may be, by way of example and not limitation, copper, silver, aluminum, nickel, alloys thereof, and combinations thereof. In some embodiments, the plurality of vias 106 is filled with a copper-containing material, such as a copper alloy. In various embodiments, the electrically conductive material in each of the plurality of filled vias has a defect ratio of less than 4.8%, less than or equal to 3%, less than or equal to 2%, or even less than or equal to 1% by volume. In some embodiments, the electrically conductive material in each of the plurality of filled vias is free of defections (i.e., voids, seams, discontinuous fillings). In some embodiments herein, the defect ratio is measured based on analysis of a scanning electron microscope (SEM) cross-section image or an X-ray CT scan. Unless otherwise specified, the defect ratio is measured based on analysis of an SEM cross-section. Accordingly, “free of defections” and “substantially defection-free” mean that there are no voids or seams or discontinuous filings visible according to the resolution of the imaging equipment.

In some embodiments, as illustrated in FIG. 9, the glass substrate is filled with an electrically conductive material, specifically copper 902. An adhesion layer 302 is present at the via entrances, connecting the copper 902 and the glass substrate sidewall 108. In certain embodiments, the adhesion layer has a thickness that ranges from 60 nm to 1500 nm, and in some embodiments, it has a length along the sidewalls 108 ranging from 50 nm to 300 nm. There is no copper or minimal deposition on the A side surface 102. In some embodiments, as shown in FIG. 10, copper also covers a portion of the outer perimeter of the vias on B side surface 104 of the glass substrate, with the area of the portion being 1.2 to 2 times the area of the vias 106.

### EXAMPLES

The following examples illustrate one or more features of the embodiments described herein.

Glass substrates (HPFS™ glass available from Corning, Incorporated) having a thickness t of 350 μm and including 25 μm diameter vias were cleaned using a standard cleaning process. In particular, the substrates were cleaned with 2.5 vol % of PK-LCG225X-1 detergent at 70° C. for 8 minute in an ultrasonic bath. The substrates were then rinsed with deionized water to remove organic residues and enrich hydroxyl groups on the substrate surfaces. After cleaning, the glass substrates showed good wettability with a water contact angle of less than 5° as measured using a DSA100 from Kruss GmbH (Germany).

Next, adhesion layer is applied on the surface of the glass substrate. In some embodiments, a cleaned glass substrate is deposited Ti/Cu (50 nm/200 nm) by physical vapor deposition in double sides to form an adhesion layer. Ti was deposited on glass in vacuum and followed by depositing Cu on top of Ti without breaking the vacuum. This process creates an oxide interface between Ti-glass and a metallic interface between Ti—Cu as an adhesion layer. This adhesion layer is deposited only covers a portion of the length in via sidewall.

Then, the A side surface and B side surface are laminated with a first and second DFR onto the adhesion layer, respectively. In some embodiments, the DFR is DuPont MX515, purchased from DuPont. The second DFR is exposed to UV light (265 nm) through a mask reticle, utilizing a contact aligner. The areas exposed to the UV light undergo crosslinking and remain on the substrate, forming a pattern, while the unexposed areas are subsequently removed from the resist. The adhesion layer is then removed through a two-step process involving copper (Cu) etching followed by titanium (Ti) etching, a method known as wet etching. This method then involves the removal of the pattern of the second DFR from the B side surface, thereby exposing the vias.

The glass substrates were then processed using a copper electroless plating kit available from Uyemura, Taiwan. The outer portion of the glass is masked with a rubber ring to allow for electrical connection during the metallization process. The plating solution used is Cupracid TP, which contains CuSO₄, H₂SO₄, Cupracid TP Leveler and Cupracid Brightene. The metallization process is carried out in a constant current mode, using a copper anode current density of 1 mA/cm² for 2 hours, followed by a current density of 2.5 mA/cm² for 7 hours. The glass is then annealed at 360° C. for 1 hour before undergoing a helium (He) hermeticity test.

FIG. 11 is XRM image showing the complete and void-free filling of the 20 um via diameters in 350 um thick glass substrate with the copper. The XRM is measured through Zeiss 520 Versa which has an approximately 1.0 um voxel resolution.

The glass substrate are placed under vacuum with a base pressure of 10-11 mbar, and helium gas is dribbled on the other side of the metallized coupon. The drop in pressure is monitored using a standard cleanroom leak checker. The observed leak rate of 7×10⁻⁸ mbar*I/sec that indicates that the metallized wafer has passed the helium hermeticity test.

It should now be understood that embodiments of the present disclosure enable through-glass vias to be formed in a thin glass substrate at an aspect ratio of greater than or equal to 5:1 and metallized such that the electrically conductive material in the filled vias has a void volume fraction of less than or equal to 5%. In particular, various embodiments enable a glass substrate including through-glass vias to be metallized without the use of a carrier. Accordingly, such processes may be used in roll-to-roll processes to fill through holes in thin, flexible glass substrates without the creation of voids.

It will be apparent to those skilled in the art that various modifications and variations can be made to the embodiments described herein without departing from the spirit and scope of the claimed subject matter. Thus it is intended that the specification cover the modifications and variations of the various embodiments described herein provided such modification and variations come within the scope of the appended claims and their equivalents.

What is claimed is:

1. A method for metallizing through-glass vias in a glass substrate, the method comprising:
a) cleaning a glass substrate, wherein the glass substrate having an A side surface and a B side surface opposite the A side surface and separated from the A side surface by a thickness t, and a plurality of vias extending through the glass substrate from A side surface to the B side surface;
b) depositing of an adhesion layer onto both the A side surface and B side surface of the glass substrate;
c) laminating of a first dry film resist (DFR) onto the adhesion layer on the A side surface and a second DFR onto the adhesion layer on the B side surface of the glass substrate;
d) making a pattern on the second DFR on the B side surface, and removing the second DFR elsewhere on the B side surface;
e) etching the adhesion layer on the B side surface everywhere except underneath the pattern of the second DFR on B side surface;
f) removing the pattern of the second DFR from B side surface so as to expose the vias;
g) applying a current to the A side surface so as to reduce copper ions into copper and maintaining the B side surface vias electrically isolated.

2. The method of claim 1, wherein the pattern of the second DFR on the B side surface comprises a plurality of patches covering the vias of the glass substrate, wherein the plurality of patches are disconnected from each other.

3. The method of claim 2, wherein the area of the patches is larger than the area of the vias so as to cover the vias.

4. The method of claim 2, wherein the patches having an area 1.2 to 2 times of the area of the vias.

5. The method of claim 1, wherein the adhesion layer is selected from at least one of titanium/copper (Ti/Cu), titanium tungsten/copper (TiW/Cu), titanium/nickel (Ti/Ni), titanium nitride (TiN), tantalum nitride (TaN), ruthenium (Ru), chromium/copper (Cr/Cu), and palladium (Pd).

6. The method of claim 1, wherein the first DFR is applied continuously over the A side surface of the glass substrate.

7. The method of claim 1, wherein the thickness t of the glass substrate is greater than or equal to 50 μm and less than or equal to 1200 μm.

8. The method of claim 1, wherein the vias have an average diameter of greater than or equal to 5 μm and less than or equal to 150 μm.

9. A glass article comprising:
a glass substrate having an A side surface and a B side surface opposite the A side surface and separated from the A side surface by a thickness t; wherein t is greater than or equal to 50 μm and less than or equal to 1200 μm;
a plurality of vias extending through the glass substrate from A side surface to the B side surface, wherein:
the vias have an average diameter of greater than or equal to 5 μm and less than or equal to 150 μm;
an aspect ratio of the thickness of the glass substrate to the average diameter of the plurality of vias is greater than 12:1 and less than or equal to 150:1;
the plurality of vias is filled with copper; wherein an adhesion layer is present at the via entrances connecting copper and a sidewall of glass substrate.

10. The glass article of claim 9, wherein the copper also covers a portion of the outer perimeter of the vias on at least one side of the surfaces of the glass substrate, wherein the area of the portion is 1.2 to 2 times the area of the vias.

11. The glass article of claim 9, wherein the adhesion layer is selected from at least one of titanium/copper (Ti/Cu), titanium tungsten/copper (TiW/Cu), titanium/nickel (Ti/Ni), titanium nitride (TiN), tantalum nitride (TaN), ruthenium (Ru), chromium/copper (Cr/Cu), and palladium (Pd).

12. The glass article of claim 9, wherein the adhesion layer has a thickness ranging from 60 nm to 1500 nm.
